(19) United States
(12) Patent Application Publication
(10) Pub. No.: US 2014/0238896 A1
(43) Pub. Date: Aug. 28, 2014

(54) SUBSTRATE CONTAINER HAVING LIMIT STRUCTURE

(71) Applicant: GUDENG PRECISION INDUSTRIAL CO., LTD., New Taipei City (TW)

(72) Inventors: CHI-TE HUANG, TAOYUAN COUNTY (TW); CHIEN-FENG WANG, NEW TAIPEI CITY (TW); SHAO-WEI LU, TAOYUAN COUNTY (TW); TIEN-JUI LIN, NEW TAIPEI CITY (TW)

(73) Assignee: GUDENG PRECISION INDUSTRIAL CO., LTD., New Taipei City (TW)

(21) Appl. No.: 13/863,526

(22) Filed: Apr. 16, 2013

(30) Foreign Application Priority Data
Feb. 25, 2013 (TW) 102106612

(51) Int. Cl. H01L 21/673

(52) U.S. Cl. CPC H01L 21/67386
USPC 206/711

(57) ABSTRACT

A substrate container having a limit structure includes a box, at least one limit structure and a door. The limit structure is disposed on a side wall of the box and has a plurality of limit grooves. Each limit groove has a first inclined surface and a second inclined surface. The angle of inclination of the second inclined plane relative to a horizontal plane corresponds to a coefficient of friction between materials of the substrate and the limit structure to lower the friction between the substrate and the second inclined plane of the limit groove, so that the substrate can ascend along the second inclined plane to get into the limit groove for the door to be closed smoothly. Through the limit structure to position the substrate, the present invention can prevent the substrate from shaking in the substrate container.

### BACKGROUND OF THE INVENTION

1. Field of the Invention

The present invention relates to a substrate container, and more particularly to a substrate container having a limit structure.

2. Description of the Prior Art

These days, due to quick development of semiconductor technology, the optical lithography technology plays an important role. As to the definition of pattern, it needs to rely on the optical lithography technology. The optical lithography technology applied to semiconductor is that the designed circuit is manufactured into a photomask which has a specific form and is pervious to light. By the principle of exposure, a light source projects on a substrate through the photomask for exposure, such that the substrate will form a specific pattern. The substrate must be kept clean, without pollution particles.

After the semiconductor process enters the deep sub-micron era, the dust-free standard for semiconductor producers is more and more strict. Though the substrate is to process reaction in a clean reaction room, the semiconductor wafer must be treated with various processes and cooperates with the process equipment. The substrate must be transported to different reaction rooms. During transportation, it is necessary to prevent the substrate from being polluted. In order to transport the substrates conveniently and to prevent the substrates from pollution, the substrates are accommodated in a seal container and the seal container is transported by automation.

In general, the seal container has a box and a door. The box has a plurality of insert grooves on left and right sides thereof to receive the substrates. The substrates are horizontally accommodated in the box. The box has an opening to put the substrates in the box or to take out the substrates. The door is disposed at the opening of the box to seal the box and to protect the substrates in the box. However, during transportation, the seal container may shake easily and the substrates in the seal container will displace and rotate because of shaking. Therefore, the box is provided with a limit member at the rear side of the box. The limit member corresponds to the door and has a plurality of grooves. Each groove is to position a substrate, preventing the substrate from displacement and rotation.

Each groove has a first inclined plane and a second plane. When the door is closed relative to the box, the door pushes the substrate and the edge of the substrate ascends along the second inclined plane and gets into the groove. When the door is disengaged from the box, the edge of the substrate will slide down along the second inclined plane to disengage from the groove. The substrate moves toward the opening. In practice, when the door is disengaged from the box, the substrate is still jammed in the groove because of the friction between the substrate and the second inclined surface of the groove, so the substrate cannot slide down along the second inclined surface smoothly.

Therefore, the present invention provides a substrate container having a limit structure. The limit structure has a plurality of limit grooves. The angle of inclination of a second inclined plane of each limit groove relative to a horizontal plane corresponds to the coefficient of friction between the materials of the substrate and the limit structure to lower the friction between the substrate and the second inclined plane, so that the substrate can ascend and descend along the second inclined plane easily.

### SUMMARY OF THE INVENTION

The primary object of the present invention is to provide a substrate container having a limit structure. The limit structure of the substrate container is to position at least one substrate received in the substrate container. The substrate can be in or out of the limit structure with ease and won't be influenced by the friction of the limit structure.

In order to achieve the aforesaid object, the substrate container having a limit structure comprises a box, at least one limit structure and a door. The door has an opening and a side wall to accommodate at least one substrate. The limit structure is disposed on the side wall of the box and has a plurality of limit grooves. Each limit groove is adapted to engage with the substrate and to limit the substrate. Each limit groove has a first inclined surface and a second inclined surface. The door is disposed at the opening. The door pushes the substrate to move along the second inclined plane to the limit groove. The angle of inclination of the second inclined plane relative to a horizontal plane corresponds to a coefficient of friction between materials of the substrate and the limit structure.

### BRIEF DESCRIPTION OF THE DRAWINGS

FIG. 1 is a sectional view showing the substrate container according to a first embodiment of the present invention;

FIG. 2 is a sectional view taken along line A-A of FIG. 1;

FIG. 3A to FIG. 3E are schematic views showing the first embodiment of the present invention when in use;

FIG. 4 is a sectional view showing the substrate container according to a second embodiment of the present invention;

FIG. 5 is a sectional view showing the substrate container according to a third embodiment of the present invention; and

FIG. 6 is a sectional view showing the substrate container according to a fourth embodiment of the present invention.

### DETAILED DESCRIPTION OF THE PREFERRED EMBODIMENTS

Embodiments of the present invention will now be described, by way of example only, with reference to the accompanying drawings.

The substrate may be jammed in the groove of the limit member of the conventional substrate container. When the door of the substrate container is closed relative to the box, the door pushes the substrate to move toward the corresponding groove. But, the substrate cannot move smoothly along the side wall of the groove toward the limit groove because of the friction between the substrate and the groove, so the door cannot be closed smoothly relative to the box. This will cause damage of the substrate. When the door is disengaged from the box, the substrate cannot slide down smoothly along the side wall of the groove to disengage from the limit groove because of the friction between the substrate and the groove, so the substrate is unable to approach the opening of the box. This results in that the substrate cannot be detected for the next process. The present invention is to provide a substrate container having a limit structure to solve the problems of the prior art.

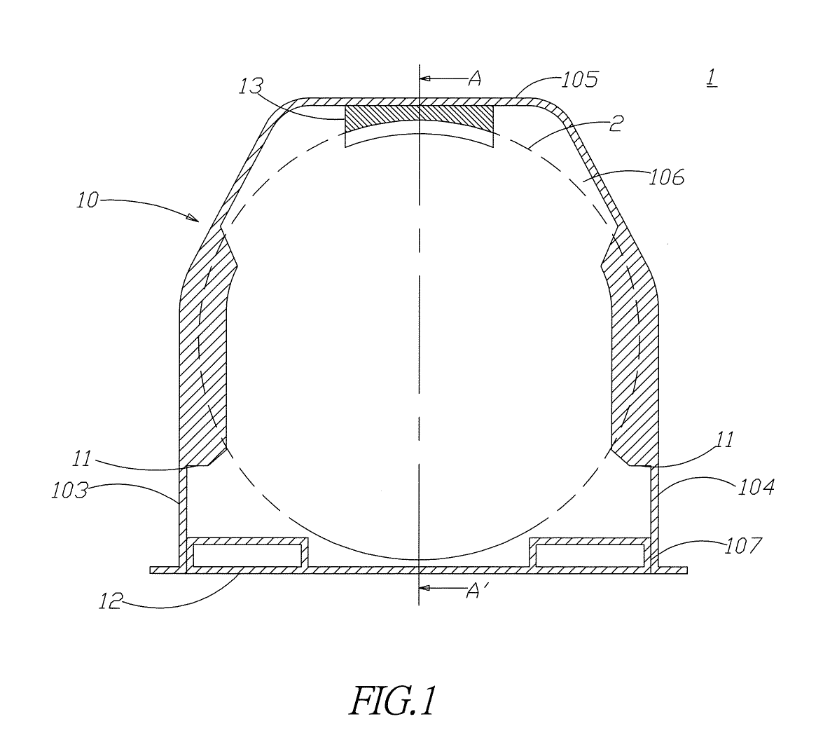

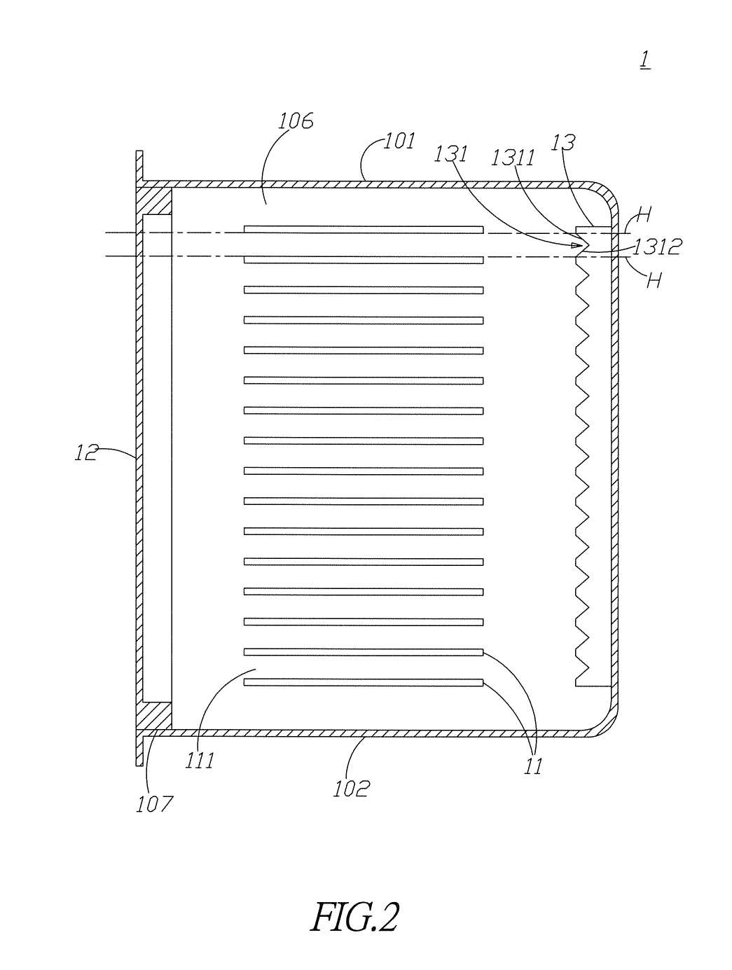

FIG. 1 and FIG. 2 are sectional views showing the substrate container according to a first embodiment of the present invention. As shown in the drawings, this embodiment provides a substrate container 1 having a limit structure. The substrate container 1 comprises a box 10 and a door 12. The box 10 has a top portion 101, a bottom portion 102, a left side wall 103, a right side wall 104 and a rear side wall 105. Two sides of the rear side wall 105 are connected to the left side wall 103 and the right side wall 104, respectively. The top portion 101 is connected with the upper edges of the left side wall 103, the right side wall 104 and the rear side wall 105. The bottom portion 102 is connected with the lower edges of the left side wall 103, the right side wall 104 and the rear side wall 105. Thus, the box 10 has an accommodation space 106 and an opening 107 communicating with the accommodation space 106. The accommodation space 106 is adapted to accommodate at least one substrate 2. The substrate 2 is a wafer, photomask, or other semiconductor substrate. The opening 107 corresponds in position to the rear side wall 105. The door 12 is mounted to the box 10 to close the opening 107 of the box 10 and corresponds in position to the rear side wall 105.

The left side wall 103 and the right side wall 104 of the box 10 are respectively provided with a plurality of support protrusions 11. The support protrusions 11 protrude from the left side wall 103 and the right side wall 104 toward the accommodation space 106. Each support protrusion 11 extends from the opening 107 toward the rear side wall 105. The support protrusions 11 are arranged in order from the top portion 101 to the bottom portion 102. The support protrusions 11 on the left side wall 103 correspond to the support protrusions 11 on the right side wall 104. Between the support protrusions 11 are a plurality of grooves 111. The grooves 111 of the left side wall 103 correspond to the grooves 111 of the right side wall 104. The substrate container 1 of the embodiment further comprises a limit structure 13. The limit structure 13 is disposed on the rear wide wall 105 of the box 10 and located in the accommodation space 106 and close to the distal ends of the support protrusions 11 of the left side wall 103 and the right side wall 104. The limit structure 13 has a plurality of limit grooves 131. The limit grooves 131 are arranged perpendicularly. The limit grooves 131 correspond in position to the grooves 111 of the left side wall 103 and the right side wall 104. Thus, the substrates 2 in the accommodation space 106 of the box 10 are located in the grooves 11 of the left side wall 103 and the right side wall 104 and the limit grooves 131 to be supported in the accommodation space 106. Each limit groove 131 has a first inclined plane 1311 and a second inclined plane 1312 opposite to the first inclined plane 1311. The first inclined plane 1311 extends from the limit groove 131 toward the top portion 101 and the second inclined plane 1312 extends from the limit groove 131 toward the bottom portion 102 to form a V-shaped limit groove 131.

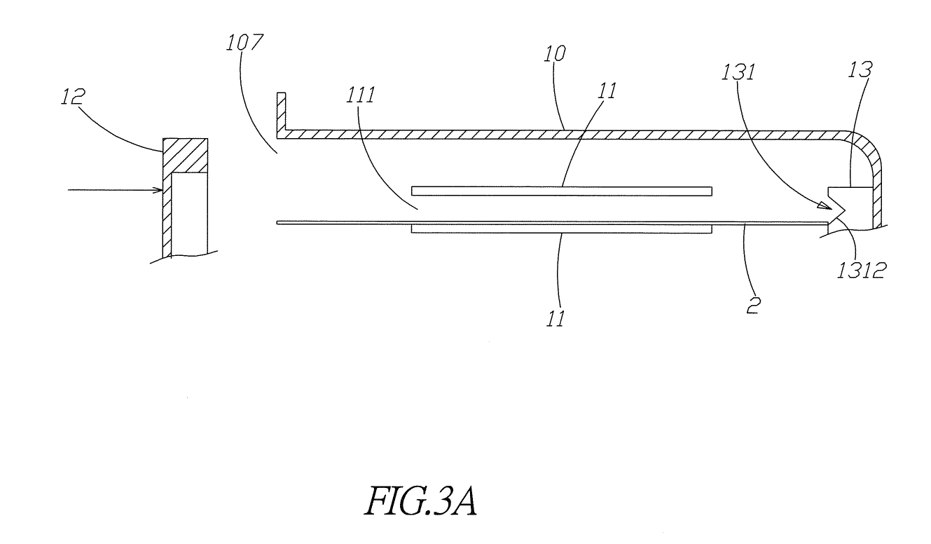

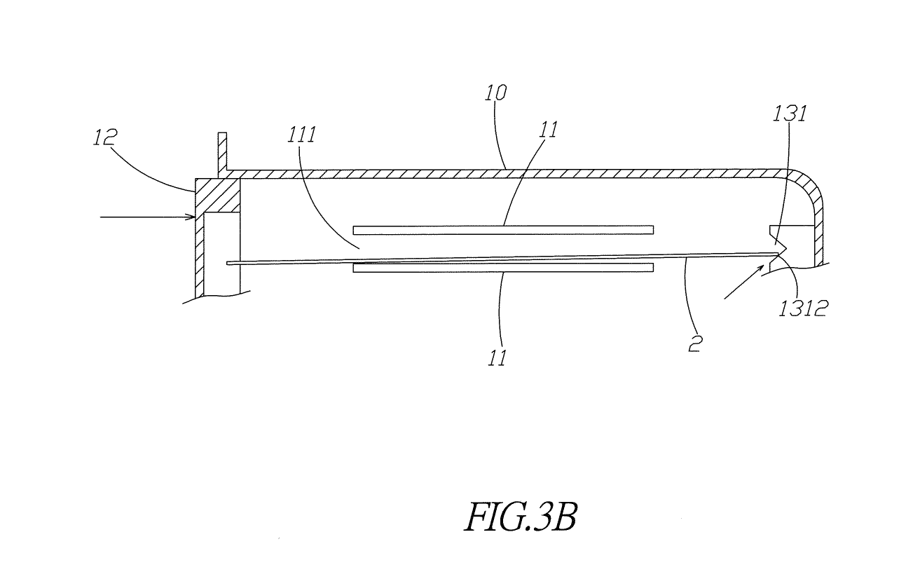

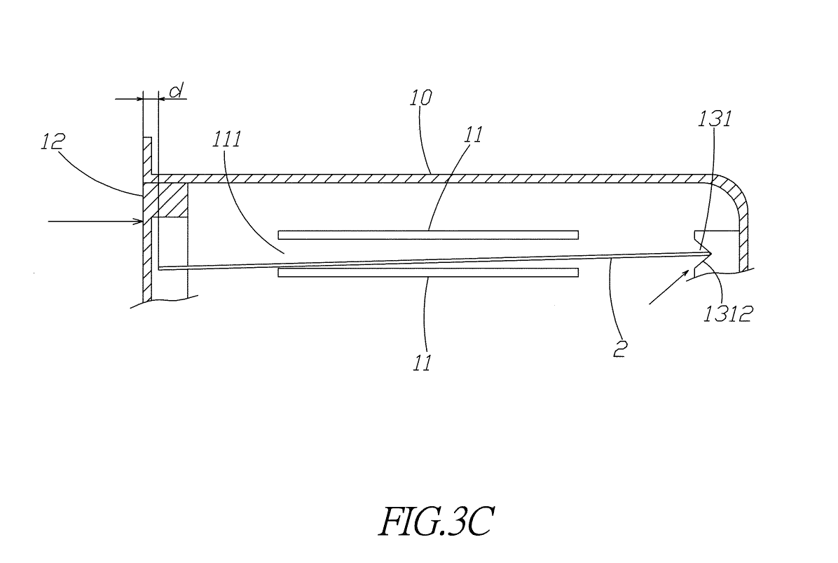

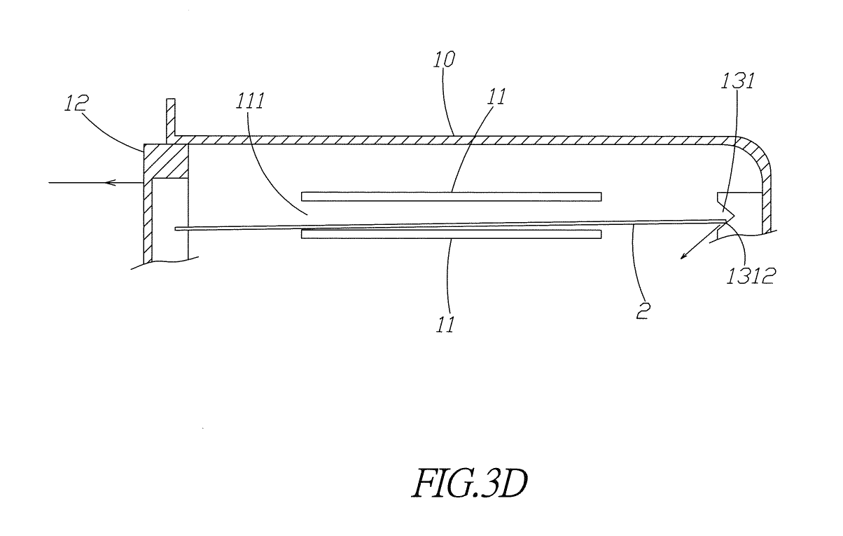

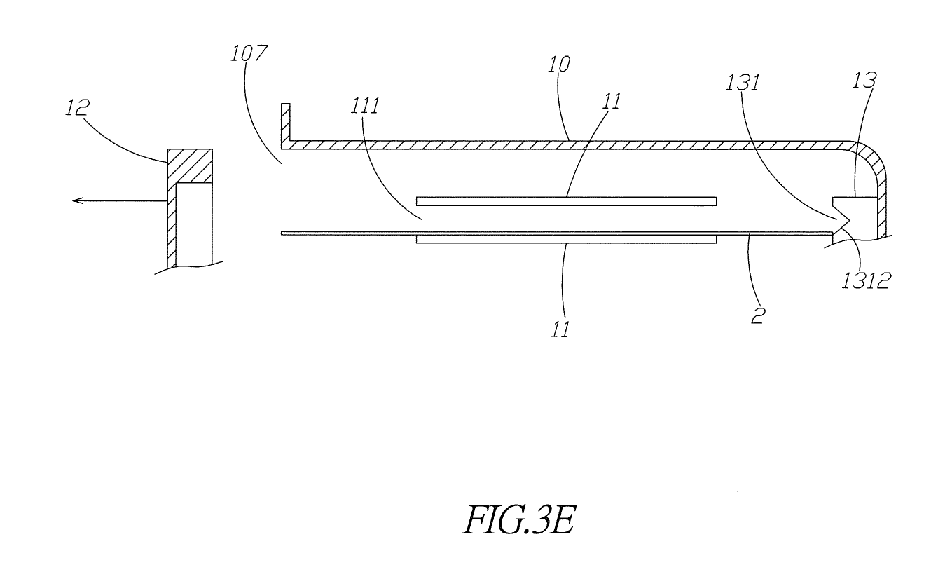

FIG. 3A to FIG. 3E shows the first embodiment of the present invention when in use. As shown in the drawings, the substrates 2 are first placed in the grooves 111 of the left side wall 103 and the right side wall 104 and the limit grooves 131. The edge of each substrate 2 is against the lower point of the second inclined plane 1312 of the corresponding limit groove 131, namely, the edge of each substrate 2 is against the outer edge of the second inclined plane 1312 of the corresponding limit groove 131, as shown in FIG. 3A. After that, the door 12 is to close the opening 107 of the box 10. At the same time, the door 12 pushes the substrates 2 to move toward the rear side wall 105. The edge of each substrate 2 is ascended along the second inclined plane 1312 of the corresponding limit grove 131 and moved toward the limit groove 131, as shown in FIG. 3B. After the door 12 is closed relative to the box 10, the substrates 2 are positioned in the limit grooves 131. At this time, the substrate 2 is away from the opening 107 of the box 10, that is, a distance “d” is defined between the edge of the substrate 2 and the opening 107 of the box 10, as shown in FIG. 3C. When the door 12 is opened relative to the box 10, the substrate 2 is not against the door 12 so the edge of the substrate 2 slides down along the second inclined plane 1312 of the corresponding limit groove 131 and moved toward the opening 107 of the box 10, as shown in FIG. 3D. Finally, the edge of the substrate 2 is located at the opening 107, as shown in FIG. 3E, for a robot arm to detect the substrate 2 and take out the substrate 2 for next process.

For the substrate 2 to ascend to the corresponding limit groove 131 along the second inclined plane 1312 or descend from the corresponding limit groove 131 along the second inclined plane 1312 and for the door 12 to be smoothly opened/closed relative to the box 10 and for detection of the substrate 2, the angle of inclination of the second inclined plane 1312 relative to a horizontal plane H corresponds to the coefficient of friction between the materials of the substrate 2 and the limit structure 13. For example, the coefficient of friction between the materials of the substrate 2 and the limit structure 13 is in the range of 0.1 to 0.4, and the angle of inclination of the second inclined plane 1312 relative to the horizontal plane H is in the range of 15 degrees to 66 degrees. In particular, when the coefficient of friction between the materials of the substrate 2 and the limit structure 13 is in the range of 0.1 to 0.2, the angle of inclination of the second inclined plane 1312 relative to the horizontal plane H is in the range of 15 degrees to 66 degrees. When the coefficient of friction between the materials of the substrate 2 and the limit structure 13 is in the range of 0.2 to 0.3, the angle of inclination of the second inclined plane 1312 relative to the horizontal plane H is in the range of 30 degrees to 60 degrees. When the coefficient of friction between the materials of the substrate 2 and the limit structure 13 is in the range of 0.3 to 0.4, the angle of inclination of the second inclined plane 1312 relative to the horizontal plane H is in the range of 50 degrees to 55 degrees.

Accordingly, the greater the coefficient of friction between the materials of the substrate 2 and the limit structure 13 is, the greater the angle of inclination of the second inclined plane 1312 relative to the horizontal plane H will be. When the coefficient of friction between the materials of the substrate 2 and the limit structure 13 is greater, the friction between the substrate 2 and the second inclined plane 1312 of the limit groove 131 will be greater. Therefore, the angle of inclination of the second inclined plane 1312 relative to the horizontal plane H must be greater. The inclination of the second inclined plane 1312 becomes greater to decrease the friction between the substrate 2 and the second inclined plane 1312, such that the substrate 2 can slide down with ease along the second inclined plane 1312. But, the angle of inclination of the second inclined plane 1312 relative to the horizontal plane H cannot be too large for the substrate 2 to be ascended smoothly along the second inclined plane 1312. On the contrary, when the coefficient of friction between the materials of the substrate 2 and the limit structure 13 is less, the friction between the substrate 2 and the second inclined plane 1312 of the limit groove 131 will be less. Therefore, the angle of inclination of the second inclined plane 1312 relative to the horizontal plane H needn't be large. The substrate 2 can slide down along the second inclined plane 1312.

In this embodiment, the angle of inclination of the second inclined plane 1312 relative to the horizontal plane H depends on the coefficient of friction between the materials of the substrate 2 and the limit structure 13. This facilitates the substrate 2 to be moved in the corresponding limit groove 131 along the second inclined surface 1312, and the door 12 is closed smoothly relative to the box 10, preventing the substrate 2 from being damaged. This also prevents the substrate 2 from not sliding down along the second inclined plane 1312 to the opening 107 to influence the next process.

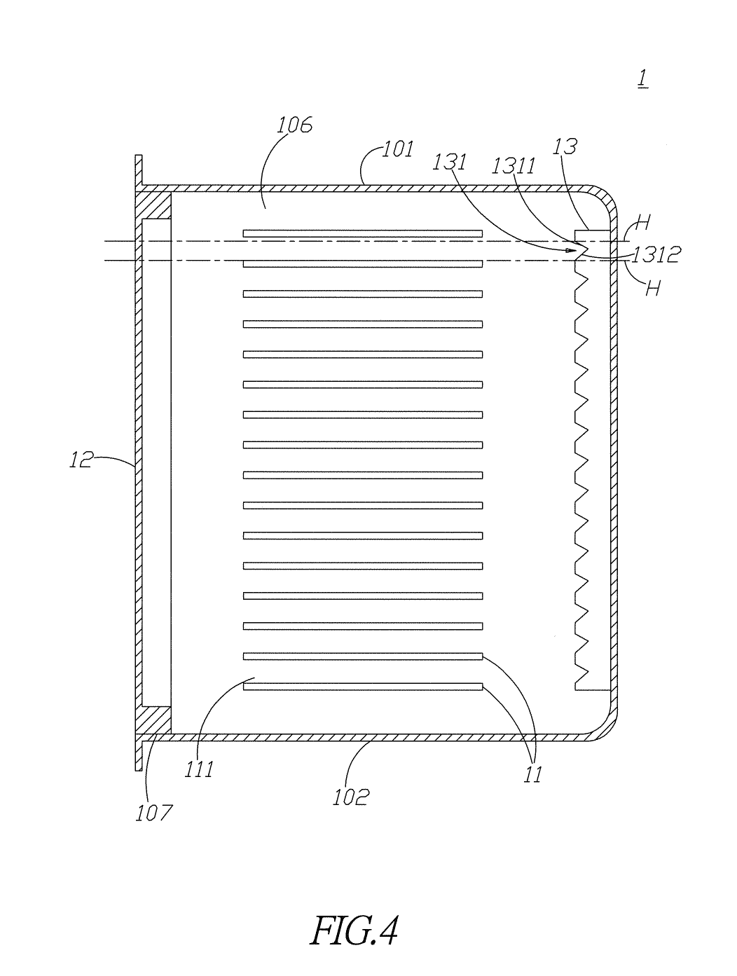

Referring to FIG. 2, the first inclined plane 1311 and the second inclined plane 1312 of each limit groove 131 of the limit structure 13 are symmetrical each other, that is, the angle of inclination of the first inclined plane 1311 relative to the horizontal plane H is equal to the angle of inclination of the second inclined plane 1312 relative to the horizontal plane H. FIG. 4 is a sectional view showing the substrate container according to a second embodiment of the present invention. As shown in the drawing, the first inclined plane 1311 and the second inclined plane 1312 of each limit groove 131 of this embodiment are not symmetrical each other, that is, the angle of inclination of the first inclined plane 1311 relative to the horizontal plane H is not equal to the angle of inclination of the second inclined plane 1312 relative to the horizontal plane H. The first inclined plane 1311 must have a certain inclination for engagement of the edge of the substrate 2 so as to position the substrate 2 in the limit groove 1311. Thus, the substrate 2 won't disengage from the limit groove 131 along the first inclined plane 1311 because of the vibration of the substrate container 1 during transportation.

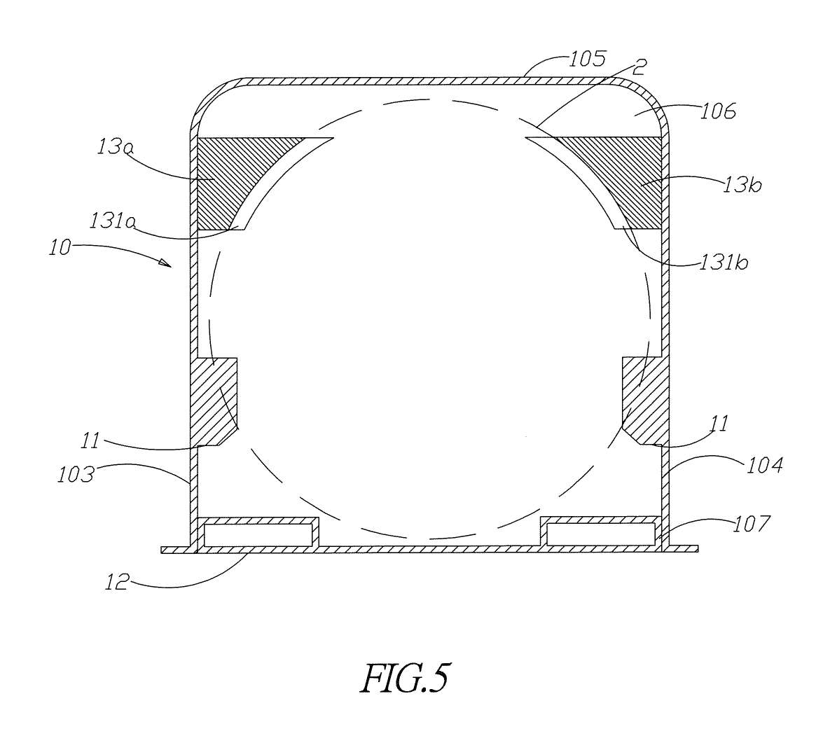

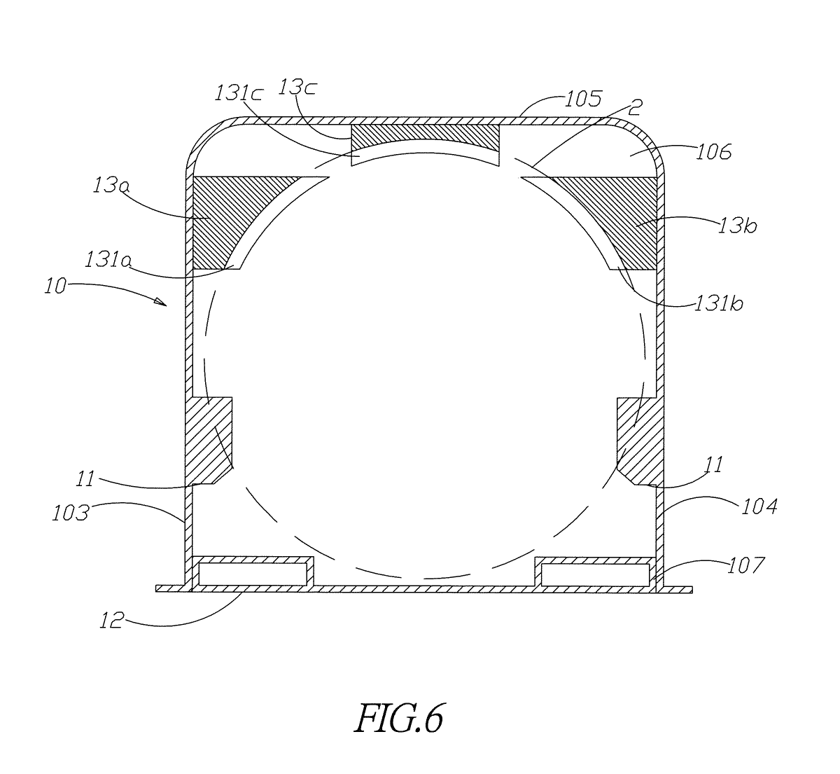

FIG. 5 is a sectional view showing the substrate container according to a third embodiment of the present invention. As shown in the drawing, this embodiment is substantially similar to the aforesaid embodiments with the exceptions described hereinafter. The substrate container 1 of the aforesaid embodiments only has one limit structure 13. In this embodiment, the substrate container 1 has a first limit structure 13a and a second limit structure 13b. The first limit structure 13a is disposed on the left side wall 103 and close to the rear side wall 105. The first limit structure 13a has a plurality of limit grooves 131a. The second limit structure 13b is disposed on the right side wall 104 and close to the rear side wall 105. The second limit structure 13b is symmetrical to the first limit structure 13a. The second limit structure 13b has a plurality of limit grooves 131b. The limit grooves 131b correspond to the limit grooves 131a of the first limit structure 13a. The configuration of the limit grooves 131a,131b of this embodiment is identical to that of the aforesaid embodiments, and won't be described hereinafter. The first limit structure 13a and the second limit structure 13b are symmetrically disposed at both sides of the rear side wall 105. The first limit structure 13a is close to the left side wall 103, and the second limit structure 13b is close to the right side wall 104. Furthermore, the rear side wall 105 may be provided with a third limit structure 13C, as shown in FIG. 6. The third limit structure 13c has a plurality of limit grooves 131c. The limit grooves 131c correspond to the limit grooves 131a of the first limit structure 13a and the limit grooves 131b of the second limit structure 13b. Thus, the limit structure can be disposed on any side wall of the box 10. The position of the limit structure in the box 10 can depend on the demand of the user, and won't be described.

To sum up, the present invention provides a substrate container. The box of the substrate container comprises at least one limit structure. The limit structure has the limit grooves. Each limit groove has the first inclined plane and the second inclined plane. The substrate in the box ascends to get into the corresponding limit groove along the second inclined plane or slides down along the second inclined plane to disengage from the corresponding limit groove. The angle of inclination of the second inclined plane relative to the horizontal plane corresponds to the coefficient of friction between the materials of the substrate and the limit structure to effectively decrease the friction between the substrate and the second inclined plane, so that the substrate can ascend and descend along the second inclined plane smoothly to improve opening/closing of the door and detection of the substrate.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A substrate container having a limit structure, comprising:
a box having an opening and a side wall to accommodate at least one substrate;
at least one limit structure disposed on the side wall of the box and having a plurality of limit grooves, each limit groove being adapted to engage with the substrate and to limit the substrate, each limit groove having a first inclined surface and a second inclined surface; and
a door disposed at the opening, the door pushing the substrate to move along the second inclined plane to the limit groove;
wherein, the angle of inclination of the second inclined plane relative to a horizontal plane corresponds to a coefficient of friction between materials of the substrate and the limit structure.

2. The substrate container having a limit structure as claimed in claim 1, wherein the coefficient of friction is in the range of 0.1 to 0.4, and the angle of inclination of the second inclined plane relative to the horizontal plane is in the range of 15 degrees to 66 degrees.

3. The substrate container having a limit structure as claimed in claim 2, wherein the coefficient of friction is in the range of 0.1 to 0.2, and the angle of inclination of the second inclined plane relative to the horizontal plane is in the range of 15 degrees to 66 degrees.

4. The substrate container having a limit structure as claimed in claim 2, wherein the coefficient of friction is in the range of 0.2 to 0.3, and the angle of inclination of the second inclined plane relative to the horizontal plane is in the range of 30 degrees to 60 degrees.

5. The substrate container having a limit structure as claimed in claim 2, wherein the coefficient of friction is in the range of 0.3 to 0.4, and the angle of inclination of the second inclined plane relative to the horizontal plane is in the range of 50 degrees to 55 degrees.

6. The substrate container having a limit structure as claimed in claim 1, wherein the side wall comprises a left side wall, a right side wall and a rear side wall, the rear side wall is connected to the left side wall and the right side wall and corresponds in position to the door, and the limit structure is disposed on the rear side wall.

7. The substrate container having a limit structure as claimed in claim 6, further comprising:
a plurality of support protrusions disposed on the left side wall and the right side wall, the support protrusions on the left side wall corresponding to the support protrusions on the right side wall, between the support protrusions being a plurality of grooves, the grooves corresponding to the limit grooves, the substrate being located in one of the grooves and one of the limit grooves.

8. The substrate container having a limit structure as claimed in claim 1, wherein the side wall comprises a left side wall, a right side wall and a rear side wall, the rear side wall is connected to the left side wall and the right side wall and corresponds in position to the door, and the limit structure comprises:
a first limit structure disposed on the left side wall and having the limit grooves; and
a second limit structure disposed on the right side wall and having the limit grooves, the second limit structure and the first limit structure being symmetrical each other, the limit grooves of the first limit structure corresponding to the limit grooves of the second limit structure.

9. The substrate container having a limit structure as claimed in claim 8, further comprising:
a third limit structure disposed on the rear side wall and having the limit grooves, the limit grooves of the third limit structure corresponding to the limit grooves of the first limit structure and the limit grooves of the second limit structure.

10. The substrate container having a limit structure as claimed in claim 8, further comprising:
a plurality of support protrusions disposed on the left side wall and the right side wall, the support protrusions on the left side wall corresponding to the support protrusions on the right side wall, between the support protrusions being a plurality of grooves, the grooves corresponding to the limit grooves, the substrate being located in one of the grooves and one of the limit grooves.

11. The substrate container having a limit structure as claimed in claim 1, wherein the angle of inclination of the first inclined plane relative to the side wall is equal to the angle of inclination of the second inclined plane relative to side wall.

12. The substrate container having a limit structure as claimed in claim 1, wherein the angle of inclination of the first inclined plane relative to the side wall is not equal to the angle of inclination of the second inclined plane relative to side wall.
